(19) United States
(12) Patent Application Publication
(10) Pub. No.: US 2010/0272527 A1
(43) Pub. Date: Oct. 28, 2010

(54) METHOD TO ATTACH OR IMPROVE THE ATTACHMENT OF ARTICLES

(75) Inventor: Steven W. Webb, Worthington, OH (US)

Correspondence Address: Diamond Innovations, 6325 Huntley Road, Worthington, OH, 43229, US

(73) Assignee: DIAMOND INNOVATIONS, INC., Worthington, OH (US)

(21) Appl. No.: 12/769,246

(22) Filed: Apr. 28, 2010

Related U.S. Application Data
(60) Provisional application No. 61/173,230, filed on Apr. 28, 2009.

(51) Int. Cl. B23P 15/28; C23C 16/44; B24B 1/00

(52) U.S. Cl. 407/118; 29/460; 451/28

(57) ABSTRACT

The disclosure relates to articles including a first material and a second material, wherein attachment between said first material and said second material is improved or created by gas-phase deposition and/or reaction to form new and adhesive solid phase(s) between the first material and the second material.

### CROSS-REFERENCE TO RELATED APPLICATIONS

This application is based on and claims the priority benefit of previously filed U.S. Provisional Patent Application No. 61/173, 230, filed Apr. 28, 2009.

### BACKGROUND

1. Field

The description set forth herein relates generally to cutting tool inserts and/or tools having one or more superabrasive cutting tips and methods of manufacturing said cutting tools.

2. Background

Machining, cutting, sawing or drilling cutting tools are often provided with removable inserts including conventional materials such as cemented carbides or ceramics (e.g. Si₃N₄, TiC—Al₂O₃ composites). FIG. 1 depicts an insert firmly held and locked into a cutting tool holder 5 by a screw or other clamping mechanism. These inserts are a disposable part of the machine cutting tool system because, in machining operations, the insert is held in contact with the work piece and eventually wears to a point requiring replacement.

Superabrasive materials containing diamond, for example, polycrystalline diamond (PCD), and/or cubic boron nitride, for example, polycrystalline cubic boron nitride (PCBN), provide enhanced machining performance over conventional materials and are also widely used as cutting tool inserts. However, due to material and/or costs, use of superabrasive materials may be impractical in many applications. Thus, due to the high material and/or production costs, fabrication techniques have been developed and optimized to reduce the usage of superabrasives, for example, on the insert, or the tip of a drill bit.

One such technique is the manufacture of a cutting tool insert that is depicted in FIG. 1. The cutting tool insert 1 may include an insert body comprising a substrate material 3 and an abrasive cutting tip comprising abrasive cutting edge(s) 2 which may be of superabrasive material, with the insert body 3 being typically fabricated out of pre-manufactured cemented tungsten carbide or hard steel or metallic material. The superabrasive cutting tip 2 may be attached to a corner or edge or center or periphery of, or otherwise in contact with, the insert body 3 by a brazing process. Brazing provides sufficient binding force to withstand the cutting forces and heat and is convenient for attaching small abrasive cutting edges. The insert 1 may then be fixed via clamp 4 or wedge to a cutting tool holder 5. The cutting tool holder is then clamped or wedged into the cutting machine.

Although prior art brazing processes reduce the material cost of manufacturing superabrasive inserts, the process, and in particular the brazing operation itself, is labor intensive and costly in some cases. The brazing process is labor intensive because the operator has to pay close attention to the joint interface, i.e., the abrasive cutting edge, the braze interface layer, and the insert body, and reposition the materials, when molten, as necessary to assure good positional accuracy and good bonding. The ultimate location of the abrasive cutting edge within the insert body and the quality of its attachment can be variable due to variable braze metal melt flow, concomitant wetting forces and the need to control the position of the tip to resist those fluid forces. Melt fluid capillary forces for non-wetting tips tend to lift the tip up and “float” the tips unless the tips are held, e.g., with ceramic pins. This is clearly shown in FIG. 3b in which the thin metal layer between the tips is seen.

It is the nature of metallic melt fluids that depending on temperature, the melt can be of such low viscosity that the fluid becomes inviscid, acting as a pure lubricant. Holding the tips becomes more difficult. Holding multiple tips in a small insert or in position on a drill tip, or to a multi-tip tool holder can become very difficult if not impossible. Indeed, if the tips are close together it may be impossible to braze each individually, without melting the other joint. This makes brazing multiple small tips to small tools exceedingly difficult. Special fixturing is required to hold the tips during braze melt, when melt fluid becomes slippery.

Brazing tip(s) to insert bodies or drill bits or tools is a highly skilled and highly technical operation. This inevitably adds cost, defects, inspection and slows manufacture of tipped tools.

Another difficulty in the brazing process is that cutting tool materials of different composition or grain size frequently require different brazing conditions, i.e., temperatures, times, braze metal formulations. Additionally, brazing dissimilar materials e.g., a cubic boron nitride cutting edge to cemented carbide insert body requires special braze alloys and conditions capable of bonding both materials simultaneously in the same process cycle. PCBN and PCD are known to be difficult to wet with brazes unless active metals, such as Ti or Fe, are incorporated into the metal formula. Such active metals are oxidation sensitive and may require use of an inert atmosphere or vacuum furnace, or very fast induction brazing, to improve the bond. They also require higher temperatures that may lead to degradation of the superabrasive material.

Since the quality of the braze joint relies on melt, flow and freezing of the braze material, time at temperature is crucial. If the process is hot for too long, the braze will thin too much or flow much further than desired. This compromises the joint and wastes valuable braze metal. If the process is too cold, braze will not flow far enough, leaving voids in the joint. A attachment process where process time is not critical would be helpful.

Since PCBN and PCD are non-wetting tips, the fluid forces are more repulsive, tending to push the superabrasive tips up and away rather than suck the tips back into the tool holder, normally made of more braze-metal wetting carbide or steel materials.

A further disadvantage of conventionally brazed inserts is that once formed, they cannot be heated above the sublimation or liquidus temperature of the braze metal in subsequent processing steps, such as, for example, chemical vapor deposition (CVD) coating of the insert. Low melting metals used in braze alloys, e.g., Sn, Zn, are volatile and the braze bond will be impaired and/or vacuum components contaminated by thermal treatment after brazing. Additionally, damage to the abrasive cutting edge or insert body from the thermal expansion/contraction cycle during brazing is possible, requiring brazing temperature and time to be kept to a minimum. In some cases, rebrazing cutting edges to correct braze flaws or regrind cutting edges is not possible. Furthermore, heat generated at the cutting edge during cutting may damage the braze attachment, particularly if attachment is created solely by meltable solids, allowing the cutting edge to displace in the holder. This will disrupt the cutting operation.

There are a number of references for specialized cutting tools that preclude the brazing requirements, including U.S. Pat. No. 5,829,924 titled “Cutting tool with Insert Clamping Mechanism,” U.S. Pat. No. 4,909,677 titled “Throw Away Cutting tool,” U.S. Pat. No. 5,154,550 titled “Throw Away Cutting Drill Bit,” and U.S. Pat. No. 4,558,974 titled “Cutting tool System for Precision Slotting.” The teachings of these patents rely on exact and complex geometrical configurations of an insert and cutting tool holder to assure that the cutting tool holder in operation securely grips the insert. These references, however, employ mechanical means of holding an insert in a cutting tool holder and not holding an abrasive cutting edge within the insert body itself.

The brazing process requires handling of three components simultaneously: (1) the tip(s), (2) the tool or insert; and (3) braze material, e.g., paste, foil, or ribbon. The braze material must be firmly attached between the tool and tip(s) up to melt temperature, at which point fluid adhesion forces may or may not hold the braze in the joint.

Additionally, braze metal systems for high-heat tool brazing typically involve significant quantities of non-oxidizable silver, up to 80% of the braze material. Oxides are known to impair braze metal flow and impair the joints. Silver is very expensive.

Accordingly, there is a need for a system for manufacturing superabrasive cutting tools without the issue of controlling the braze melt fluid capillary forces. This would allow non-contact adhesive attachment of non-metal-wetting cutting tips to metal wetting tool holder materials.

### SUMMARY

An embodiment includes a cutting tool. The cutting tool includes an abrasive cutting edge and a material to which the cutting edge(s) is bonded thereon. The abrasive cutting edge may include a superabrasive material. This abrasive cutting edge may be non-deformable. The abrasive cutting edge may have a higher hardness than the material comprising the tool or tool holder. The material may be an insert body or tool body, drill bit, substrate or tool holder. The material may include one or more of the following: steel, metals, powdered-metal, carbide or ceramic or mixtures thereof.

The attachment of the superabrasive tip or material to the tool body is accomplished and/or improved by gas-phase infiltration (aka “CVD”) of metallic and/or ceramic precursors into gaps and/or seams between incompletely contacting gas-accessible surfaces of the material and superabrasive tip(s). The precursors deposit and react or transform in the gaps and/or seams to form solid metal or ceramic phase(s) which themselves bond adhesively to the tool holder and to the superabrasive tip(s). The reactive gases convert to solids, which fill gaps and/or seams between tip and material, as well as create new adhesion forces between cutting edge(s) and material holder. The solid film formed coats all gas-accessible surfaces of the tool, and tip(s), including cracks, fissures, seams, gaps and contact areas. Where the distance between those coated surfaces is less than ½ the coating thickness, a solid ceramic bridge bond will form. It is this solid bridge bond that holds the tip(s) to the tool via adhesive forces.

The bond may be ceramic or metal, micro or polycrystalline or even single-crystalline. It may comprise a single material layer or multiple layers. The thickness of the solid bond formed via gas phase CVD reaction can be adjusted thin, to maintain electrical conductivity or thick to allow attachment of roughly ground or sawn cutting tip(s).

The solid adhesive material may be a refractory ceramic thus the attachment will be capable of withstanding higher temperatures than conventional brazed joints. The body may have specific geometrical arrangement with the abrasive cutting edge(s) to improve bonding. In this way, there is no fluid phase and no fluid phase capillary forces causing tip(s) to move. Wetting of the tip(s) or material holder is inconsequential. There is no need to hold or fix or position the tip(s) during attachment.

Original attachment or creation of gaps and seams between the cutting edge(s) and material may include press-fit, interference-fit, thermal-shrink fit, chemical adhesives e.g., epoxies, or conventional solder or braze metals or simply gravity. Tool tip surfaces may be polished to minimize seam thickness, and thus minimize coating thickness required to form bridge bonds. Tool tip materials of various types, e.g., ceramic, PCBN, diamond or carbide, may require different solid films to optimize specific adhesion.

### BRIEF DESCRIPTION OF THE DRAWINGS

FIG. 1 is a top and side view of an example of a cutting tooling setup for turning.

FIG. 2 is a depiction of how the attachment strength is measured.

FIG. 3 is photo of an insert prior to braze and grinding and one after braze and grinding, showing the major parts of the insert: steel tool material (3) or insert body, carbide support (6) of the PCBN cutting tip (7).

FIG. 4 is a series of 3 photos of an insert after CVD gas phase deposition of TiN ceramic showing the presence of new ceramic between the steel and carbide part of the cutting tip and the absence of any new ceramic between PCBN and steel.

### DETAILED DESCRIPTION

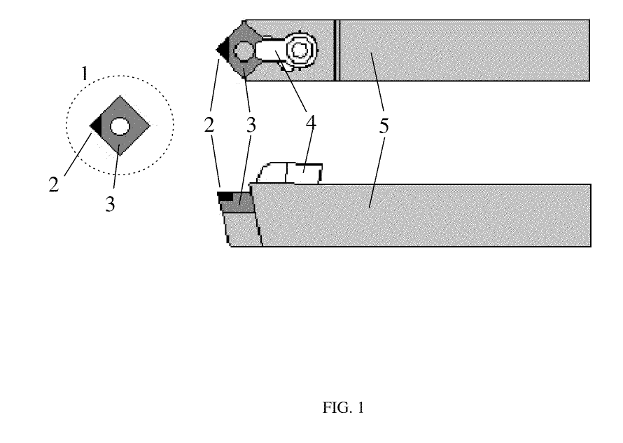

As used herein, the term “insert” refers to pieces of superabrasive, ceramic and/or carbide (such as tungsten carbide) or alternative cutting material mechanically held, brazed, soldered, or welded into position on dies or cutting tools, and discarded when worn out, others being fitted in their place. An example is illustrated in FIG. 1, where insert 1 includes insert body 3 and abrasive cutting edge 2. Also see A Dictionary of Machining (Eric N. Simmons, Philosophical Library, New York, 1972).

As used herein, the term “cutting tool holder” refers to the rigid body that holds an insert or inserts firmly in place so that they can be utilized in a turning, milling, boring, cutting, or drilling application (see for example FIG. 1).

The invention generally relates to insert 3 including an abrasive cutting edge 2 and an insert body 3. In particular, the insert 1 includes a material insert-molded onto a portion of the abrasive cutting edge 2.

Sintering techniques known well in the art may make the abrasive cutting edge 2. The abrasive cutting edge 2 may include any material that can be used in machining, cutting, or drilling applications, including but not limited to carbides, ceramics or superabrasive such as silicon nitride, silicon carbide, boron carbide, titanium carbide-alumina ceramics such as titanium carbide, fused aluminum oxide, ceramic aluminum oxide, heat treated aluminum oxide, alumina zirconia, iron oxides, tantalum carbide, cerium oxide, garnet, cemented carbides (e.g. WC—Co), synthetic and natural diamond, zirconium oxide, cubic boron nitride, laminates of these materials, mixtures, and composite materials thereof. These materials may be in the form of a single crystal or sintered polycrystalline bodies. Generally, the abrasive cutting edge may be of any material that is less deformable (harder) or more abrasion resistant than the work piece material and more abrasion resistant than the material or insert body.

In one embodiment of the invention, the abrasive cutting edge 2 may have a thickness that is similar to that of the insert body 3. This combination allows for use of the top and bottom cutting edges from the abrasive cutting edge. The thick cutting edges may be in the form of single crystals, sintered polycrystalline bodies, or laminate bodies with the abrasive material on the upper and lower layers of the assembly.

Abrasive compacts or blanks including polycrystalline diamond (PCD) or polycrystalline cubic boron nitride (PCBN) are commercially available from a number of sources, including Diamond Innovations, Inc. under the trade names COMPAX® and BZN®, respectively. PCD and PCBN compacts may be self-bonded, or may include a suitable bonding matrix of about 5% to about 80% by volume. The bonding matrix may be a metal such as cobalt, iron, nickel, platinum, titanium, chromium, tantalum, copper, or an alloy or mixture thereof and/or carbides, borides, or nitrides or mixtures thereof. The matrix additionally may contain a recrystallization or growth catalyst such as aluminum for CBN or cobalt for diamond.

The compacts may be PCBN discs having a thickness of about 1 to about 15 mm In another embodiment, the PCBN compacts may have a thickness of about 1.6 to about 6.4 mm The forming of the compacts may be done via processes known in the art including Electro Discharge Machining (EDM), Electro Discharge Grinding (EDG), laser, plasma, and water jet. Geometries of cut pieces can be predetermined and computer controlled to maintain tight tolerances.

In an embodiment, the PCBN blank may be formed into shape via means of an abrasive water jet. In another embodiment of the invention, the PCBN blank may be laser-etched at selected positions on the surface according to a predetermined computer controlled pattern, e.g., forming a polygonal shape with two of the sides forming about an 80° triangle with about 5.0 mm cutting edge length, and the rest of the straight sides forming a zigzag shape for subsequent interlocking with the mating feature in the insert body.

In an embodiment, the abrasive cutting edge may have a cutting edge with a length “a” of about 0.5 mm to about 25.4 mm, comprising angles of about 20 to about 90° in any plane of reference. In a second embodiment, the abrasive cutting edge may be of thickness of about 0.5 mm to about 7 mm The abrasive cutting edge may be a circle, oval, octagon, hexagon, partial or complete ring shape, or any shape, or size used in cutting tools.

Prior to CVD treatment, pre-cleaning of the surfaces may be required. Removal of non-bonding oxide and carbon contamination is typically conducted either by oxidation or hydrogen reduction.

The cutting edge(s) are attached by some method to the tool holding material. The cutting tool(s) is then placed in a CVD (chemical vapor deposition) reaction vessel, whereupon air is removed and replaced by gases comprising both inert and reactive species. Metallic deposition may employ gases comprising metal carbonyl or metal-acetal-acetonates, for example, iron pentacarbonyl. Ceramic deposition precursors may include TiCl4, NH3, CH4, AlCl3, (CH3)3Al etc or mixtures thereof. The gases penetrate via diffusion into gaps, seams, contact voids, and deposit on any and all heated solid surfaces, external or internally gas-accessible, in the equipment. Upon condensation on the surface, the condensed phases chemically react to form a new solid phase. For e.g., TiCl4+NH3 TiC solid+gas phase HCl. This solid phase adhesively bonds to the solid surfaces depending on chemical affinity. The quality of the solid phase (crystal perfection, density) depends on temperature and affinity to the solid surface(s) upon which they condense. The process of infiltration, condensation and reaction to form a new solid phase continues until the surfaces are covered or coated with new solid phase and reaction is stopped.

Gas accessibility is determined by the gas diffusion, which depends on temperature and pressure. Lower pressure allows deeper diffusion of reactive gases into seams and gaps in the tool assembly. Gas deposition, reaction and solidification rates forming a solid must be controlled to prevent premature “plugging” of narrow gaps and seams, thus reducing the film contact area and joint strength. This typically requires the temperature be lowered, or gas phase partial pressure of reactants be adjusted. Finally, the quality of the film formed, its crystallinity and crystal orientation, depends on temperature and time. If the film is formed and quenched too quickly, it may be of poor quality and crack either within the film or at the film-tip or film-tool interface.

It is important that the gas-phase precursors react with solid surfaces indiscriminately, regardless of orientation in the reactor. So-called “line-of-sight” deposition processes, e.g., PVD, will not be as effective as the gas-phase precursors will not penetrate gaps and seams, thus reducing the area of adhesion and adhesion strength considerably.

Furthermore, non line-of-sight CVD coating does not require tools to be flipped over and processed multiple times to form a uniform coating. CVD coats all gas-accessible surfaces in one furnace cycle.

Gas phase reactions that may also be considered CVD include any gas-solid reactions such as oxidation, hydration, or carburization. The solid constituents may adsorb onto surfaces first, then react and crystallize, or may form above the surface and deposit by solid-surface tension forces prior to reaction and crystallization.

Post-CVD treatment e.g., annealing may be conducted to improve the quality of the film or film-tip/film-tool adhesion.

Key process variables in the deposition of this “gas-phase” or “dry braze” process include reactor temperature and pressure, as well as cleanliness and state of the original solid surfaces upon which condensation and reaction are to occur. Reactor temperatures may range from about 200° C. to about 2000° C. and pressures may range from about 100 Pa to about 150 Pa. Reactors that may be used include, but are not limited to CVD reactors, microwave CVD (MWCVD) reactors, plasma enhanced CVD (PECVD) reactors and other gas-phase processes.

There are no new forces in the gas-phase deposition processes, thus there is no movement of the cutting edge(s) with respect to the material of the cutting tool or tool insert. Once the gaps and seams are filled and bridged, the process effectively stops. Solid material continues to accumulate on external surfaces.

The abrasive cutting edge will conventionally comprise a hard layer e.g., sintered diamond, bonded to a softer e.g., sintered tungsten carbide. However, it may also comprise a single-layer of hard material or many layers of different materials, such as pure metal or pure ceramic layers, themselves bonded to the hard diamond layer and/or carbide layer. These layers may function as thermal insulators, space filling (to reduce diamond cost), and anti-friction or braze layers.

Inserts of any variety of shape, size, or thickness, attachable to a wide variety of cutting tool holders for use in turning, milling, and boring, sawing, and drilling applications may be created. The bonded insert of the present invention may contain multiple abrasive cutting edges (limited only by insert shape) and may not require external clamps, body wedges, or fixture constraints.

Cutting tools containing superabrasive cutting edges come in a wide variety of sizes and shapes, including boring tools, reamers, and drills, as well as milling tools.

It has also been found that bonding superabrasive materials to similar materials can be accomplished by the “dry braze” process, e.g., bonding PCBN to PCBN, carbide to carbide or other materials.

The examples below are merely representative of the work that contributes to the teaching of the present invention, and the invention is not to be restricted by the examples that follow.

### Example-1

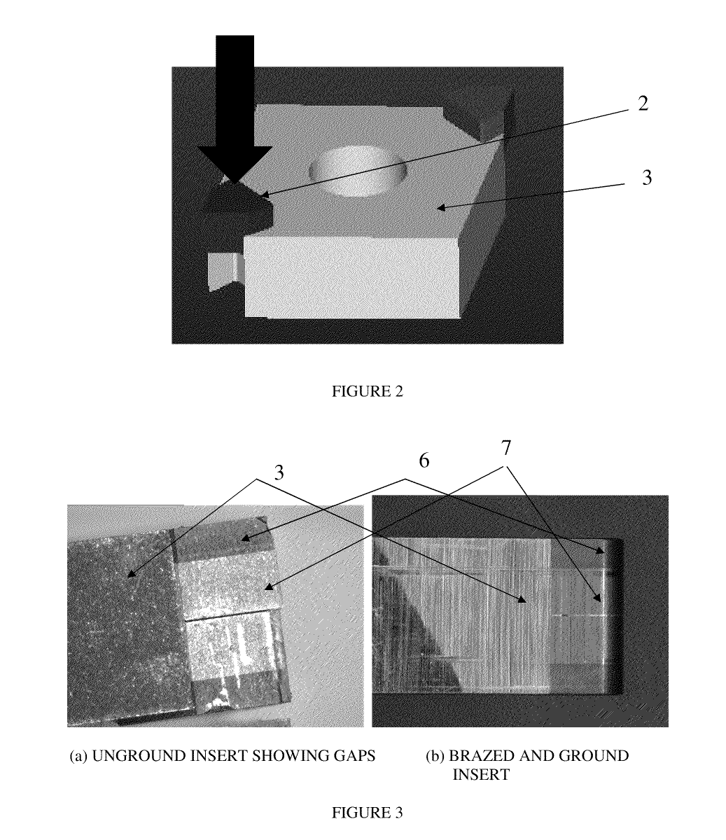

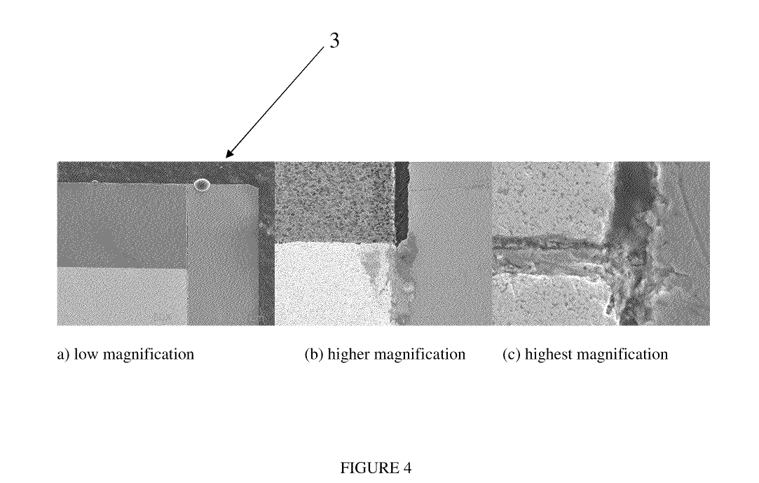

Inserts SNGA43 comprising PCBN grade BZN6000 were fabricated by pressing precision cut BZN6000 tips from sintered blanks comprising PCBN bonded to a layer of WC/Co, into precision-cut hard A2 steel bodies. Tip attachment strength was measured by pushing on a tip (ref. FIG. 2) until it is pushed out of the pocket, observing maximum force required. Measured strength was 46, 35 and 191 lbs of force. It is the nature of press fit involving EDM-cut surfaces that dimensional imprecision due to asperities and surface contaminants leads to variable, but adequate, attachment strength.

To improve attachment strength, the same inserts from example-1 were placed in a heated oven at 500° C. for 12 hours in air. This causes thermal expansion opening of the gaps or seams in the assembled insert, allowing exposure to hot oxygen gas and subsequent oxidation of the steel and carbide surfaces to form new solid phase iron oxides, hydroxides against W- or Co-oxides on the carbide. There is a weight gain of the insert is nearly 0.9%, entirely attributed to oxidation of steel. Precision micrometers indicate a size increase of the entire steel body external surfaces so of nearly 0.020 mm. This same new solid film will also be formed in the gap between steel and tips, formed by thermal expansion and between asperities non-yielded in the original press fit operation. These new oxide phases adhere to both carbide and steel and thus augment strength derived from interference or press fit. Upon cooling the new solid phase effectively increases the interference fit between low-expanding PCBN and high-expanding steel, thus improving attachment. Finally, the new oxides fill gaps and increase the contact area between tip and steel body. Measured strength was 368, 478, 365 lbs, an increase of almost 4× and a reduction in variability of attachment.

### Example-2

DNGA43 inserts were fabricated with PCBN grade HTM by pressing precision cut tips into precision cut pockets in hard steel. Attachment was measured via push out test, testing the resistance to axial stress in the push out direction, to be 254, 279 lbs. Upon oxidation at 600° C. for 6 hours in air, attachment strength increased to 421, 424 lbs. (push out test measurement). Having a larger tip, the D insert shows increased benefit of oxidation to attachment strength.

### Example-3

Press fit assembled DNG43 inserts were brazed with CuAg in a furnace at 850 C., and then ground on all sides and chamfered to form DNG432 cutting inserts. Grinding forces did not move or dislodge any of the cutting tips. Attachment was measured via push out test and the tip attachment strengths of the brazed and ground inserts were: 190, 224, and 57 lbs, average 157 lbs. Press fit assembled oxidized DNG43 inserts from example-2 were ground on all sides and chamfered to form DNG432 cutting inserts. These inserts were processed in a CVD reactor at 1000° C., using TiCl4, CH4, NH3, AlCl3 gases and oxygen to form multiple solid phases comprising TiN, TiC, TiCN and aluminum oxide. Attachment was measured via push out test and the tip attachment strengths after CVD dry brazing were found to be: 130 lbs., 112 lbs., 180 lbs. and 159 lbs, averaging 145 lbs. Tip attachment strength from CVD gas-phase brazing was as good as conventional furnace brazing a melt metal.

### Example-4

PCBN grade HTM tips were placed into precision-cut oversize carbide pockets to form a CNMA43 cutting tool insert. The pocket was shaped like a pine-tree in order to create mechanical interlocking between tip and tool body. The gap between tip and carbide pocket was <0.020 mm for most of the area of contact. The assembled inserts were placed on a metal tray and processed in a CVD reaction furnace cycle at 1000° C., admitting reactant gases TiCl4, H2 and CH4 that form adherent ceramic films on all surfaces of the insert assembly, PCBN and carbide. Where the gap between tip and tool body surfaces was <0.020 mm, the coating was able to span and bridge the gap, thus forming a solid bond. These “dry-brazed” inserts were ground to fabricate CNGA432 0.004″×30 degrees chamfer; 0.001″ hone and tested in hard turning at 656 sfpm, 0.010″ depth of cut, 0.007″ ipr, dry OD turning of HRC61 8620 steel. The insert performed with no tip movement or breakage.

### Example-5

Small 5 mm pieces of HTM PCBN on carbide were set on top of each other, carbide to carbide, and placed in the CVD reactor as in example 4. The small parts were bonded together well such that they could be ground to a point. Carbide can be bonded to carbide with this CVD dry braze ceramic film process. Polishing is not required.

### Example-6

12 mm squares of HTM PCBN on carbide were placed on top of each other, carbide-to-carbide, in the same CVD reactor cycle discussed above. The parts were bonded together and survived periphery grinding. However, upon top/bottom grinding, the inserts showed bend cracks. The penetration of the bonding ceramic film was observed to be only 4 mm The lack of complete penetration of the gap by the reactant gases left a gap in the joint that allowed the carbide parts to defect upon top/bottom grinding, causing them to crack.

### Example-7

HTM PCBN small triangles were polished to <0.002 mm smoothness, placed on ground alumina oxide wafers, and processed in the same CVD reactor cycle as above. After the cycle, all gas-phase-accessible surfaces were coated with adherent ceramic film, except the white aluminum oxide. Thus, the tips which were in contact with alumina fell apart instantly, confirming no bridge bond formation with any adhesion of the ceramic film to aluminum oxide and no joint alumina-to-carbide were formed.

It will be appreciated that several of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A cutting or shaping tool comprising:
a. a cutting or shaping edge(s); and
b. a tool holding material
wherein attachment between said cutting edge(s) and tool holding material is improved, or created, by gas-phase deposition and/or reaction to form new and adhesive solid phase(s) between the cutting edge(s) and tool holding material.

2. The cutting tool according to claim 1, wherein the material is a cutting tool insert body or drill body.

3. The cutting tool according to claim 1, wherein the cutting tool is a reamer, drill or other tool.

4. The cutting tool according to claim 1, wherein the cutting edge(s) of the cutting tool is designed to carry the chip away from the insert body, thus to not melt or soften or degrade the body.

5. The cutting tool according to claim 1, wherein the cutting edge(s) is coated prior to, during, or after the gas-phase deposition and reaction process, and creates a new phase of mass or volume between edge(s) and tool holding material, conducted to improve adhesion bonding to the tool holding material.

6. The cutting tool according to claim 1, wherein the cutting edge has a higher hardness than the material comprising the body.

7. The cutting tool according to claim 1, wherein the attachment of cutting edge(s) to tool holder material is improved or effected by a CVD, MW-CVD, PE-CVD or other gas-phase process, such that there is no fluid phase intermediate or capillary forces between cutting edge(s) and tool holding material.

8. A method of forming a cutting tool, comprising:
providing a cutting edge;
providing a material to form an insert and/or tool body; and,
attaching, or improving attachment, of the cutting edge(s) to material forming the insert body via CVD deposition of solids between cutting edge(s) and insert body material.

9. The method according to claim 8, wherein the material is a cutting tool insert body or drill body.

10. The method according to claim 8, wherein the cutting tool is a reamer, drill or other tool.

11. The cutting tool according to claim 8, wherein the cutting edge(s) of the cutting tool is designed to carry the chip away from the insert body, thus to not melt or soften or degrade the body.

12. The method according to claim 8, wherein the cutting edge has a higher hardness than the material comprising the body.

13. The method according to claim 8, wherein the attachment of cutting edge(s) to insert and/or tool body is improved or effected by CVD deposition such that there is no fluid phase intermediate or capillary forces between cutting edge(s) and the insert and/or tool body.

14. The method according to claim 8, further comprising the step of coating the insert body and all solid surfaces on the cutting tool or insert via the same CVD process used to adhesively bond or improving bonding between cutting edge(s) and tool holding material.

15. The method according to claim 8, further comprising the step of grinding the cutting tool insert.

16. An article comprising:
a. a first material; and
b. a second material,
wherein attachment between said first material and said second material is improved or created by gas-phase deposition and/or reaction to form new and adhesive solid phase(s) between the first material and the second material.

17. The article according to claim 16, wherein an edge of the first material is coated prior to, during, or after the gas-phase deposition and reaction process, and creates a new phase of mass or volume between edge(s) and second material, conducted to improve adhesion bonding to the tool holding material.

18. The cutting tool according to claim 16, wherein the attachment of the first material to the second material is improved or effected by a CVD, MW-CVD, PE-CVD or other gas-phase process, such that there is no fluid phase intermediate or capillary forces between the first material and second material.
